(19) United States
(12) Patent Application Publication
(10) Pub. No.: US 2009/0205708 A1
(43) Pub. Date: Aug. 20, 2009

(54) REDUCED TRANSMITTANCE PHOTOVOLTAIC CONVERSION DEVICE FOR HIGH SPECTRAL IRRADIANCE

(75) Inventor: Philippe Samson, Nice (FR)

Correspondence Address: LOWE HAUPTMAN & BERNER, LLP, 1700 DIAGONAL ROAD, SUITE 300, ALEXANDRIA, VA, 22314, US

(73) Assignee: THALES, NEUILLY SUR SEINE (FR)

(21) Appl. No.: 12/095,895

(22) PCT Filed: Dec. 1, 2006
(86) PCT No.: PCT/FR2006/051270

§ 371 Date: Jan. 27, 2009

(30) Foreign Application Priority Data
Dec. 2, 2005 (FR) 0553698

(51) Int. Cl. H01L 31/0216

(52) U.S. Cl. 136/256; 257/E31.119

(57) ABSTRACT

A device (D), dedicated to photovoltaic conversion under high spectral irradiance has: i) a photovoltaic cell (CP) having a lower face provided with a conductive layer (CC) and an upper face (FSC) provided with a carrier collection grid (G). The device also has ii) at least one protective screen (EP) made of glass placed above the cell (CP) and limitation means (SC) responsible, when the device (D) is placed under strong incident radiation of a known spectrum, for limiting the access of a part of this incident radiation to the cell (CP) so as to reduce its thermal heating.

### CROSS-REFERENCE TO RELATED APPLICATIONS

The present Application is based on International Application No. PCT/FR2006/051270, filed on Dec. 1, 2006, which in turn corresponds to French Application No. 0553698 filed on Dec. 2, 2005, and priority is hereby claimed under 35 USC §119 based on these applications. Each of these applications are hereby incorporated by reference in their entirety into the present application.

### FIELD OF THE INVENTION

The invention relates to photovoltaic conversion devices.

### BACKGROUND OF THE INVENTION

A “photovoltaic conversion device” is here understood to mean a device comprising on the one hand at least one photovoltaic cell comprising at least one semiconductor element responsible for converting part of an incident ray that it receives into electric current and having a lower face provided with a conductive layer and an upper face provided with a grid for collecting the carriers generated during the conversion, and on the other hand at least a glass screen, for example of the “coverglass” type, placed above the cell in order to protect it against radiation and to ensure a correct emissivity.

In certain use conditions photovoltaic devices receive very significant incident radiation which leads to significant heating at each of its photovoltaic cells, along with saturation of the carrier injection system within the photovoltaic structure (i.e. mono or multijunctions). This is the case notably when they are subject to a high concentration of solar flux, typically higher than 3 (×3), in the context of terrestrial, aeronautical or spatial applications, or indeed when they are directed towards a star emitting radiation and located a short distance from the latter, as for example in the context of solar missions.

As is known by a person skilled in the art, this significant heating leads to a fall in the output of the photovoltaic conversion of the semiconductor elements, for example of around 20% to around 50% in the case of silicon and for a temperature varying from 25° C. to 300° C.

To solve this problem, at least two solutions have been proposed. The first solution consists in inclining the photovoltaic surface in such a way as to reduce the flux of incident radiation. This solution necessitates a particular support which appreciably increases the weight and offers no selectivity as a function of the wavelength.

The second solution consists in surrounding each photovoltaic cell with optical reflectors of the OSR (“Optical Solar Reflector”) type, located on the thermally conductive elements so as to capture part of the calories that diffuse coming from the photovoltaic cells.

A third solution consists in combining the first two solutions, when the surface ratio between the cell and the OSR necessitates further reduction in the temperature range by inclining the surface relative to the incident flux.

These three solutions introduce significant temperature gradients in the plane of the surface and perpendicular to this plane, necessitating a particular support which appreciably increases the weight and offers no selectivity as a function of the wavelength. In addition, in the case of the second solution and for a constant spatial requirement, the conversion output of the device is reduced due to the fact that the space previously occupied by some photovoltaic cells is now occupied by the optical reflectors.

Moreover, in the case of performance deterioration in directing the angle of incidence, a drop in performance may occur combined with destruction of the photovoltaic conversion device for thermal and/or electric reasons.

As no known solution is completely satisfactory in terms of weight and cost for a given performance and/or in terms of maintaining performance, the invention therefore has the aim of improving the situation.

### SUMMARY OF THE INVENTION

To this end it proposes a photovoltaic conversion device, designed to be used notably under high spectral irradiance, i.e. beyond its initially anticipated field of use or its initially anticipated design conditions, and comprising on the one hand at least one photovoltaic cell comprising a lower face provided with a conductive layer and an upper face provided with a carrier collection grid, and on the other hand at least one protective screen made of glass placed above the cell.

This photovoltaic conversion device is characterized by the fact that it comprises means responsible, when the device is placed under strong incident radiation (of a known spectrum), for limiting the access of a part of this incident radiation to the cell in order to reduce its thermal heating.

It is important to note that it is being assumed here that the materials used are characterized by high emissivity, avoiding the inhibition of the consequences of low absorption.

The device according to the invention may comprise other features which may be taken separately or in combination, and notably:
its limitation means may be arranged in the form of at least one semi-reflecting layer structure located in the path of the propagation of the radiation, between space and the upper face of the cell, and responsible for reflecting towards space at least a chosen part of a portion of the incident radiation that does not play a part in the photovoltaic conversion;
   the layer structure may, for example, be joined to an upper face of the protective screen, opposite the upper face of the cell. In this case, the protective screen comprises a lower face directed towards the upper face of the cell and joined to this, for example by means of an adhesive transparent to at least part of the incident radiation or any other fixing or retention device;
   in a first variant the layer structure may, for example, be joined to a lower face of the protective screen, directed towards the upper face of the cell, and comprises a lower face directed towards the upper face of the cell and joined to this, for example by means of an adhesive transparent to at least part of the incident radiation or any other fixing or retention device;
   in a second variant the layer structure may, for example, be defined on the upper face of the cell in the space situated between the collection elements of the collection grid;
   the layer structure may, for example, comprise a layer of metal oxide(s) of a thickness chosen depending on the wavelengths of the part of the incident radiation chosen to be reflected towards space;
   the layer structure may, for example, comprise at least two layers of metal oxide(s) of respective thicknesses chosen depending on the wavelengths of the part of the incident radiation chosen to be reflected towards space;
its limitation means may consist of the collection grid, this comprising collection elements connected to each other and having a total surface covering the upper face of the cell chosen so as to be equal to a chosen fraction of the surface of this upper face.

The invention is particularly well suited, although in a nonexclusive manner, to electrical generators, photodetectors, solar or stellar “sensors”, and concentrators used in terrestrial and aeronautical applications and in space missions.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIG. 1 illustrates very schematically a first example embodiment of a photovoltaic conversion device according to the invention;

FIG. 2 illustrates very schematically a second example embodiment of a photovoltaic conversion device according to the invention;

FIG. 3 illustrates very schematically a third example embodiment of a photovoltaic conversion device according to the invention; and

FIG. 4 illustrates very schematically a fourth example embodiment of a photovoltaic conversion device according to the invention.

The appended drawings may serve not only to complete the invention but also contribute to its definition if necessary.

### DETAILED DESCRIPTION OF THE INVENTION

The object of the invention is to allow limitation of the heating of photovoltaic cells of a photovoltaic conversion device in the presence of high, or even very high, incident radiation (or high spectral irradiance). One of its interests lies more particularly in the possibility of making the photovoltaic structure operate in a more usual regime of injection of carriers into the junction(s).

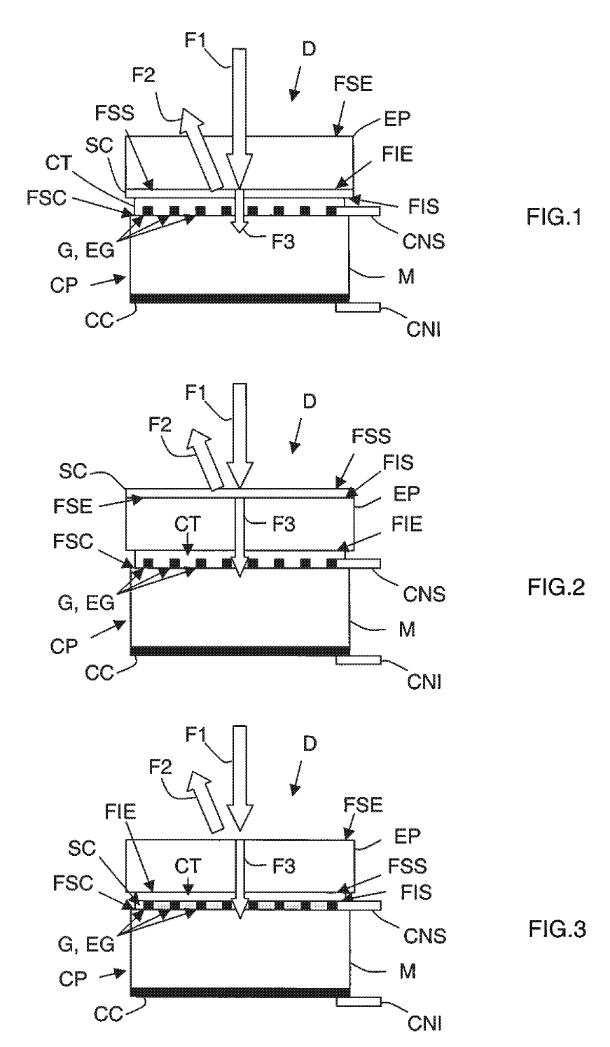

In the following the photovoltaic conversion device is considered to comprise only a single photovoltaic cell in order to simplify its description. But usually such a device comprises numerous photovoltaic cells connected to each other in series or in groups. It will furthermore be considered, purely by way of illustration, that it is part of an electric generator. To begin with, reference is made to FIG. 1 in order to describe a first example embodiment of a photovoltaic conversion device according to the invention.

A device according to the invention D comprises at least one photovoltaic cell CP, of the conventional type, and at least one protective screen EP made of glass, for example of the coverglass type, located above a face, referred to as the upper face (FSC), of the cell CP.

In the following, a face directed towards the incident spectral flux will be designated by “upper” and a face oriented in a manner opposite an upper face by “lower”.

Furthermore, a photovoltaic cell CP is here understood to be an assembly consisting of a conversion material MC, responsible for converting an incident ray coming from space and of a known spectrum (arrow F1) into a carrier (electrical) current, a conductive layer CC, joined to a lower face of said conductive material MC and connected to a lower connector CNI, and a carrier collection grid G, joined to an upper face FSC of the conversion material MC and responsible for collecting the carriers generated by the conversion material MC during photoelectric conversion. The conversion material MC may, for example, be Si, GaAs, InP or CdTe, or indeed any combination of at least two of the preceding materials or of materials with a high photovoltaic susceptibility.

The grid G generally consists of elements for collecting the carriers EG, in a longitudinal form, approximately parallel to each other and connected in parallel with an upper connector CNS.

It is important to note that the conversion material MC has a known spectral response. In other words, it is only able to convert part of the incident radiation, the wavelengths of which are included in a known interval. The complementary part of the incident radiation, the wavelengths of which are situated outside this conversion interval, cannot therefore be used to produce carriers and it therefore contributes only to the heating of the photovoltaic cell CP placed on its support.

According to the invention, the device D also comprises limitation means SC or EG which are responsible, when it is placed in a strong incident radiation (of known spectrum), for limiting the access of a part of this incident radiation to the cell CP (which amounts to limiting the transmittance of the device D) in order to reduce its thermal heating.

These limitation means may, for example, be arranged in the form of at least one semi-reflecting layer structure SC located in the path of the propagation of the incident radiation (arrow F1), between space and the upper face FSC of the photovoltaic cell. This structure SC, which is schematically illustrated in FIGS. 1 to 3, is responsible for reflecting towards space (arrow F2) at least a chosen part of the complementary part of the incident radiation that does not play a part in the photovoltaic conversion. Consequently, it is responsible for allowing at least part of the part of the incident radiation that is usable for the photovoltaic conversion (and the wavelengths of which are included in the conversion interval) to pass towards the conversion material MC (arrow F3).

Hence, the reflected radiation no longer contributes to the heating of the photovoltaic cell CP.

It is important to note, although this is not apparent in FIGS. 1 to 3, that the structure SC comprises one or more semi-reflecting layers. Each layer is, for example, produced by depositing (possibly under vacuum) metal oxides, such as ZnO, Al₂O₃, Ta₂O₅ or SiO₂ for example. The type of material used and the thickness of each layer, and possibly the number of layers, are chosen depending on the wavelengths of the radiation which are to be reflected towards space (arrow F2) and on the wavelengths of the radiation which is to be transmitted to the photovoltaic cell CP (arrow F3). This choice is made by spectral analysis of the anticipated incident ray and of the spectral response of the photovoltaic cell CP taking account of this anticipated incident radiation. It allows optimization of the optical energy balance as a function of the spectral response of the photovoltaic cell CP.

The multilayer structure may for example comprise an optical filter or a distributed Bragg reflector (DBR).

The respective types and thicknesses of the layers of material(s) are determined by modeling as a function of the characteristics of the incident flux, and of the spectral response of the photovoltaic structure. The thicknesses may, for example, vary from a few nanometers to a few micrometers.

The layer structure SC may be located in at least three different places.

In the example embodiment illustrated in FIG. 1, the layer structure SC comprises an upper face joined to the lower face FIE of the protective screen EP, which screen is directed towards the upper face FSC of the photovoltaic cell CP.

In this case, the lower face FIS of the layer structure SC is joined to the upper face FSC of the photovoltaic cell CP by means, for example, of an adhesive CT which is transparent to at least part of the incident radiation and notably to that which is usable for the photovoltaic conversion. Instead of an adhesive it is possible to use any other fixing or retention device.

In the example embodiment illustrated in FIG. 2, the layer structure SC is joined to the upper face FSE of the protective screen EP, which is opposite the upper face FSC of the photovoltaic cell CP.

In this case, the lower face FIE of the protective screen EP is joined to the upper face FSC of the photovoltaic cell CP by means, for example, of an adhesive CT which is transparent to at least part of the incident radiation and notably to that which is usable for the photovoltaic conversion. Instead of an adhesive it is possible to use any other fixing or retention device.

In this embodiment, it may be advantageous to provide an appropriate electrical adaptation (for example, integrated protection diodes) in order to avoid mismatching of association in a network of various cells, which mismatching might lead to destruction of the device D (phenomenon called “hotspot”).

In the example embodiment illustrated in FIG. 3, the layer structure SC is joined to the upper face FSC of the photovoltaic cell CP in the free space situated between the collection elements EG of its collection grid G. It therefore fills, at least partly, the space that separates the longitudinal elements EG. The collection elements EG are here in effect considered to reflect the incident radiation. In a variant, it is conceivable that the layer structure SC fills the entire free space situated between the collection elements EG and covers them with a chosen thickness.

The lower face FIE of the protective screen EP is here joined to the upper face FSC of the photovoltaic cell CP, via the grid G and the layer structure SC, by means, for example, of an adhesive CT which is transparent to at least part of the incident radiation and notably to that which is usable for the photovoltaic conversion. Instead of an adhesive it is possible to use any other fixing or retention device.

In the example embodiments illustrated in FIGS. 1 to 3 the limitation means comprise only a single layer structure SC. But variants are conceivable in which they comprise a layer structure SC joined to the upper face FSE of the protective screen EP and/or a layer structure SC joined to the lower face FEI of the protective screen EP and/or a layer structure SC joined to the upper face FSC of the conversion material MC of the photovoltaic cell CP.

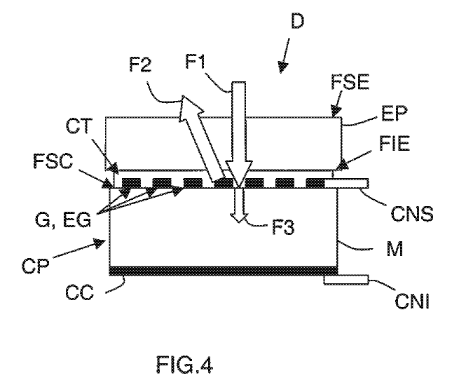

Reference will now be made to FIG. 4 in order to describe a fourth example embodiment, different from the three preceding ones, which relies on the use of at least one semi-reflecting layer structure SC.

In this example embodiment, the limitation means consist directly of the collection grid G. More precisely, its collection elements EG are used to reflect a part of the incident radiation (arrow F2). Here the reflection is not selective due to the fact that the incident flux which reaches (arrow F3) the conversion material MC is limited only by increasing the total surface of the covering of the upper face FSC of the cell CP by the collection elements EG. The proportion of covering of the conversion material MC by the collection elements EG is chosen depending on the maximum flux of incident radiation that said conversion material MC is allowed to receive. By limiting the incident flux the transmittance of the device D is limited, which allows the heating of the photovoltaic cell CP to be reduced, and hence the reduction in its photovoltaic conversion output to be limited.

The proportion of covering that allows the heating to be limited results from modeling and from a compromise between the thermal and electric balances of the device D. The order of magnitude of this covering proportion is, for example, greater than or equal to 50%.

The invention is not limited to the embodiments of the photovoltaic conversion device described above, solely by way of example, but includes all the variants that someone skilled in the art might envisage in the scope of the claims below.

Thus, in what precedes, an application of the invention to photovoltaic devices of the electrical generator type have been described. But the invention is not limited to this application. It also relates to photovoltaic conversion devices such as saturable photodetectors, solar or stellar sensors, and concentrators. In these latter cases, the device substitutes for and in the place of the detector, the sensor and the solar cell respectively.

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1-10. (canceled)

11. A photovoltaic conversion device (D) in the presence of a high spectral irradiance comprising:
a photovoltaic cell having a lower face provided with a conductive layer and an upper face provided with a carrier collection grid and at least one protective screen made of glass placed above said cell, comprising limitation means arranged, when said device is placed under strong incident radiation of a known spectrum, in order to limit the access of a part of said incident radiation to said cell so as to reduce its thermal heating.

12. The device as claimed in claim 11, wherein said limitation means are arranged in the form of at least one semi-reflecting layer structure located in the path of the propagation of said radiation, between space and the said upper face of said cell, and arranged so as to reflect towards space at least a chosen part of a portion of the incident radiation that does not play a large part in the photovoltaic conversion.

13. The device as claimed in claim 12, wherein said layer structure is joined to an upper face of said protective screen, opposite the upper face of said cell, and in that said protective screen comprises a lower face directed towards the upper face of said cell and joined to this.

14. The device as claimed in claim 13, wherein said lower face of the protective screen is joined to the upper face of said cell by means of an adhesive transparent to at least part of said incident radiation.

15. The device as claimed in claim 13, wherein said lower face of the protective screen is joined to the upper face of said cell by means of a fixing or retention device.

16. The device as claimed in claim 12, wherein said layer structure is joined to a lower face of said protective screen, directed towards the upper face of said cell, and comprises a lower face directed towards the upper face of said cell and joined to this.

17. The device as claimed in claim 16, wherein said lower face of said layer structure is joined to the upper face of said cell by means of an adhesive transparent to at least part of said incident radiation.

18. The device as claimed in claim 16, wherein said lower face of said layer structure is joined to the upper face of said cell by means of a fixing or retention device.

19. The device as claimed in claim 12, wherein said layer structure is defined on the upper face of said cell in the space situated between the collection elements of said collection grid.

20. The device as claimed in claim 12, wherein said layer structure comprises a layer of metal oxide(s) of a thickness chosen depending on the wavelengths of said part of the incident radiation chosen to be reflected towards space.

21. The device as claimed in claim 12, wherein said layer structure comprises at least two layer of metal oxide(s) of respective thicknesses chosen depending on the wavelengths of said part of the incident radiation chosen to be reflected towards space.

22. The device as claimed in claim 11, wherein said limitation means includes said collection grid, this comprising collection elements connected to each other and having a total surface covering said upper face of said cell chosen so as to be equal to a chosen fraction of the surface of this upper face.
